(19) United States
(12) Patent Application Publication
(10) Pub. No.: US 2015/0098844 A1
(43) Pub. Date: Apr. 9, 2015

(54) FAN MODULE

(71) Applicant: COMPAL ELECTRONICS, INC., Taipei City (TW)

(72) Inventors: I-Feng HSU, Taipei City (TW); Chang-Yuan WU, Taipei City (TW); Chih-Chin CHIEN, Taipei City (TW)

(73) Assignee: COMPAL ELECTRONICS, INC., Taipei City (TW)

(21) Appl. No.: 14/274,768

(22) Filed: May 11, 2014

(30) Foreign Application Priority Data
Oct. 9, 2013 (TW) 102136591

(51) Int. Cl. F04D 29/053; F04D 25/08; H05K 7/20; F04D 25/06

(52) U.S. Cl. CPC F04D 29/053; F04D 25/062; F04D 25/0646; F04D 25/0693; F04D 25/08; H05K 7/20172
USPC 417/354; 415/170.1

(57) ABSTRACT

A fan module used in an electronic apparatus is provided. The electronic apparatus includes an upper cover and a lower cover. The fan module includes a fan housing, a fixing shaft, a bearing, and a fan body. The fan housing is mounted on the lower cover. The fixing shaft includes a first end and a second end. The first end is mounted on the fan housing. The second end passes out of the fan housing. The bearing includes a first ring and a second ring. The first ring is pivotally connected to the second ring. The first ring is disposed around the outer edge of the fixing shaft. The fan body is disposed around the outer edge of the second ring, so as to rotate relative to the fixing shaft.

### RELATED APPLICATIONS

This application claims priority to Taiwan Application Serial Number 102136591, filed Oct. 9, 2013, which is herein incorporated by reference.

### BACKGROUND

1. Technical Field

The present disclosure relates to a an module.

2. Description of Related Art

Electric motors are widely used in many electronic apparatuses, such as lathes, electric drills, chainsaws, tape players, CD-ROM drives, hard disk drives, pumping machines, hair dryers, vacuum cleaners, refrigerators, air conditioners, fans, etc. In present information age, the dependences of the human race on the electronic products are growing. Owing to the features of high speed, high efficacy, and being unaffected by geographical localities, variety of portable electronic devices has become mainstream, such as notebook PCs, cell phones, PDAs (Personal Digital Assistant). The portable electronic devices have become indispensable application tools in the modern life and work.

In order to achieve the purpose of making an electronic apparatus has an impact size and high efficacy, active cooling elements installed in the electronic apparatus must be miniaturized correspondingly. The cooling elements can exhaust the air in the electronic apparatus to the outside, so as to lower the temperature in the electronic apparatus and prevent the cooling elements from damaged by heat. Fans are one kind of commonly used cooling elements, which can be seen in large machines, power supplies of computers, refrigerators, etc.

In present, in a commonly used known fan module, the rotors (i.e., the rotating shaft, the fan body, etc.) rotate together with the stator, so as to generate airflow to exhaust the heat in an electronic apparatus. However, if the known fan module is applied in a thinner notebook computer, the housing of the notebook computer may easily contact the rotors of the fan module when an external force deforms the housing. The housing and the rotors that are rubbing against each other not only generate sharp noises but also generate unexpected wear and tear to elements in the fan module, so that the lifetime of the fan module is significantly reduced.

### SUMMARY

In order to solve the aforementioned problems, an aspect of the present disclosure is a fan module. The fan module replaces a rotating shaft that originally rotates with a fan body by a fixing shaft, and protrudes the fixing shaft out of the fan module to bear loads, so as to prevent the problem that the fan body stops rotating caused by an external load.

In an embodiment of the disclosure, a fan module is used in an electronic apparatus. The electronic apparatus includes an upper cover and a lower cover. The fan module includes a fan housing, a fixing shaft, a bearing, and a fan body. The fan housing is mounted on the lower cover. The fixing shaft includes a first end and a second end. The first end is mounted on the fan housing. The second end passes out of the fan housing. The bearing includes a first ring and a second ring. The first ring is pivotally connected to the second ring. The first ring is disposed around the outer edge of the fixing shaft. The fan body is disposed around the outer edge of the second ring, so as to rotate relative to the fixing shaft.

The fan module of the present disclosure can also additionally install a supporting rib at the original location of the rotating axis and passes the supporting rib out of the fan module to bear loads, so as to prevent the problem that the fan body stops rotating caused by an external load.

In another embodiment of the disclosure, a fan module is used in an electronic apparatus. The electronic apparatus includes an upper cover and a lower cover. The fan module includes a fan housing, a supporting rib, a hollow shaft, a bearing, and a fan body. The fan housing is mounted on the lower cover. The supporting rib includes a first end and a second end. The first end passes out of the fan housing to be connected to the lower cover. The second end passes out of the fan housing to be connected to the upper cover. The hollow shaft is pivotally connected to the outer edge of the supporting rib. The bearing includes a first ring and a second ring. The first ring is pivotally connected to the second ring and disposed around the outer edge of the hollow shaft. The second ring is mounted on the fan housing. The fan body is disposed around the outer edge of the hollow shaft, so as to rotate relative to the supporting rib together with the hollow shaft.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a perspective view of an electronic apparatus according to an embodiment of the disclosure;

FIG. 2A is a perspective view of a fan module according to an embodiment of the disclosure;

FIG. 2B is an exploded view of the fan module in FIG. 2A;

FIG. 3 is a cross-sectional view showing that the fan module in FIG. 2A is disposed in the electronic apparatus in FIG. 1;

FIG. 4 is an exploded view of the fan module and a lower cover of the electronic apparatus according to an embodiment of the disclosure; and

FIG. 5 is a cross-sectional view showing that a fan module is disposed in the electronic apparatus in FIG. 1 according to another embodiment of the disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

An aspect of the present disclosure is a fan module. More particularly, the fan module replaces a rotating shaft that originally rotates with a fan body by a fixing shaft, and protrudes the fixing shaft out of the fan module to bear loads, so as to prevent the problem that the fan body stops rotating caused by an external load.

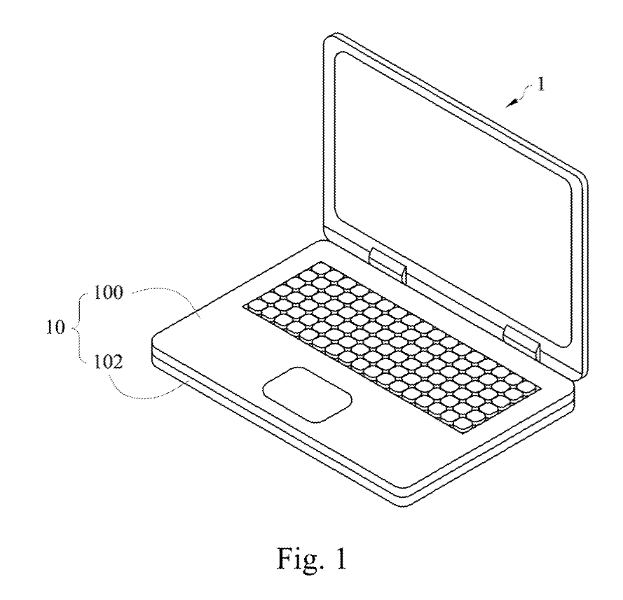

FIG. 1 is a perspective view of an electronic apparatus 1 according to an embodiment of the disclosure.

As shown in FIG. 1, the electronic apparatus 1 that uses the fan module of the disclosure can be a computer (e.g., a personal PC, a notebook PC, a tablet PC, etc.) or a consumer electronics product (e.g., a projector, a game console, etc.), but the disclosure is not limited in this regard. The electronic apparatus 1 that uses the fan module of the disclosure can be any electronic product in which heat sources are installed. The fan module of the disclosure not only can dissipate the heat in the electronic apparatus 1 but also can bear external load without generating noises.

As shown in FIG. 1, the electronic apparatus 1 takes a notebook PC as an example, but the disclosure is not limited in this regard. The electronic apparatus 1 includes a host 10. The host 10 of the electronic apparatus 1 includes an upper cover 100 and a lower cover 102. The main core components (not shown) of the electronic apparatus 1 are installed in the host 10 (i.e., between the upper cover 100 and the lower cover 102). The components of the fan module in the electronic apparatus 1 are introduced in detail below.

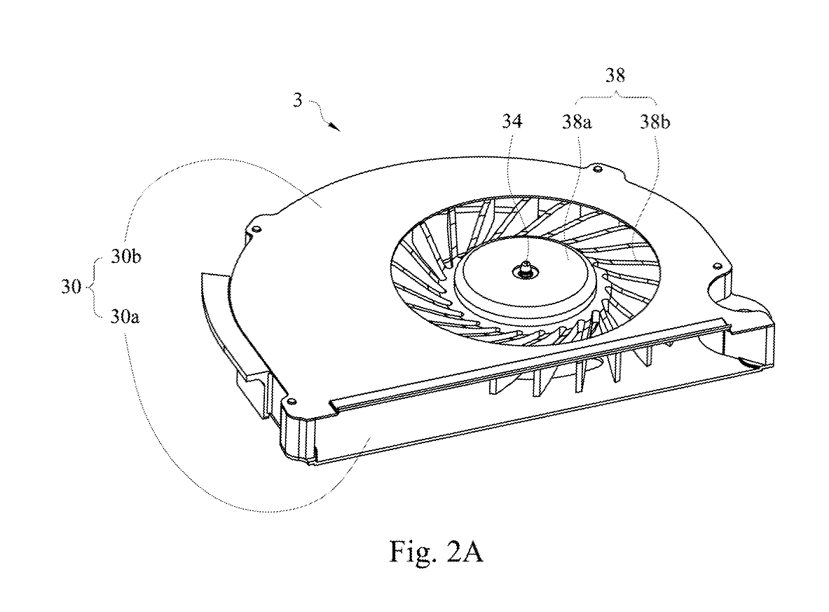

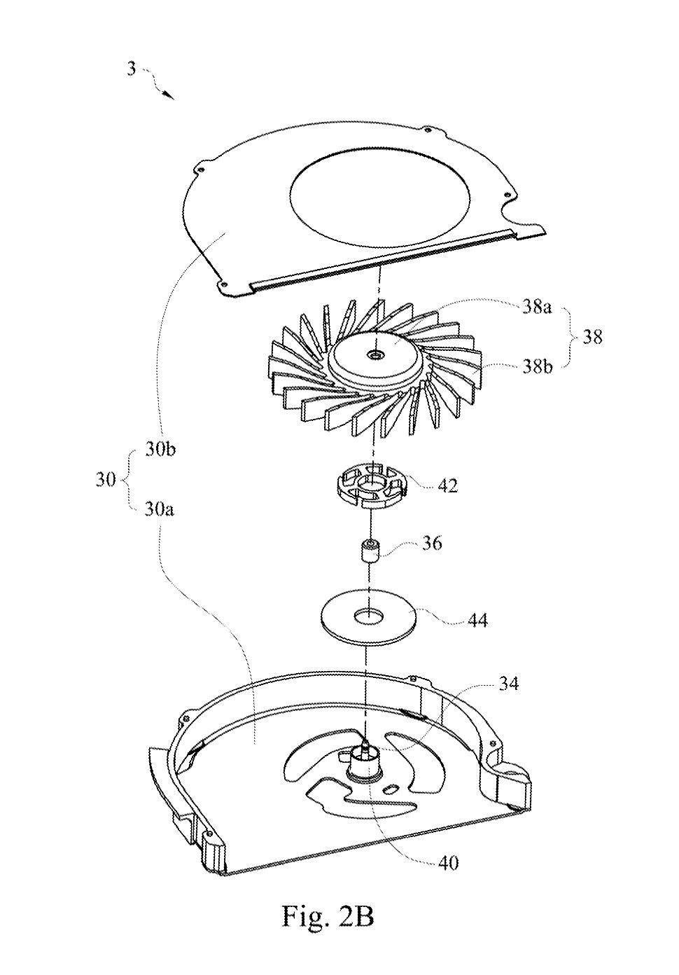

FIG. 2A is a perspective view of a fan module 3 according to an embodiment of the disclosure. FIG. 2B is an exploded view of the fan module 3 in FIG. 2A.

As shown in FIG. 2A and FIG. 2B, the fan module 3 includes a fan housing 30, a fixing shaft 34, a bearing 36, a fan body 38, a bushing 40, a stator 42, and a circuit board 44. The fan housing 30 includes a fan base 30a and a fan cover 30b, and the fan housing 30 is mounted between the upper cover 100 and the lower cover 102 of the electronic apparatus 1 by a plurality of fixing members (not shown). The fan base 30a and the fan cover 30b of the fan housing 30 can be mounted to each other by engaging or locking, but the disclosure is not limited in this regard. The fixing shaft 34, the bearing 36, the fan body 38, the bushing 40, the stator 42, and the circuit board 44 of the fan module 3 are disposed between the fan base 30a and the fan cover 30b. After the fan module 3 is completely assembled, the fixing shaft 34 partially protrudes out of the fan cover 30b. The functions of the aforementioned components of the fan module 3 and the connection relationship between the fan module 3 and the electronic apparatus 1 are described in detail below.

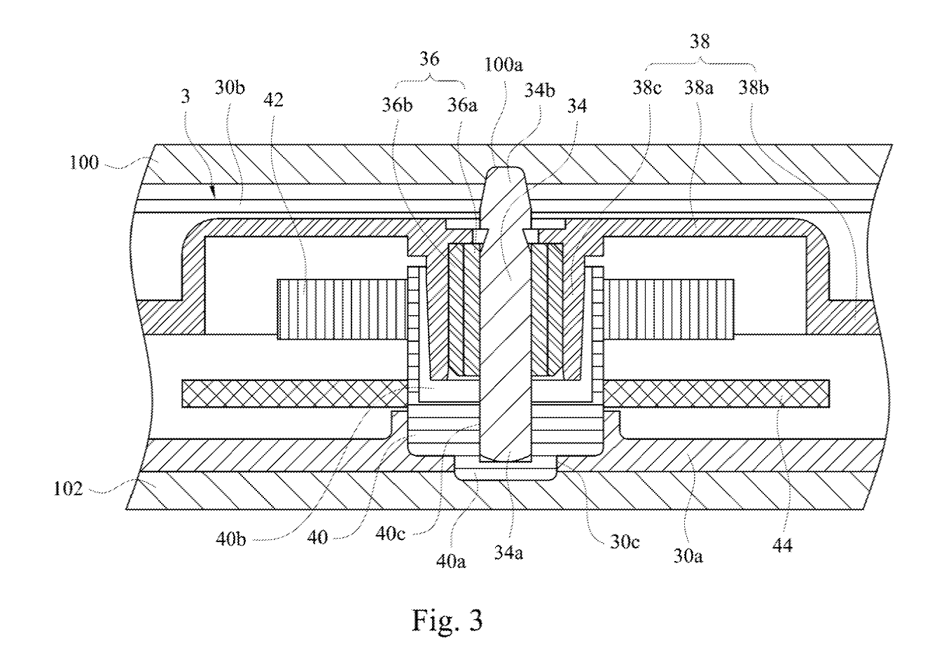

FIG. 3 is a cross-sectional view showing that the fan module 3 in FIG. 2A is disposed in the electronic apparatus 1 in FIG. 1.

In practice, the fan housing 30 can be mounted to the upper cover 100 or the lower cover 102 of the electronic apparatus 1, or a main board (not shown) installed in the electronic apparatus 1. In the embodiment, the fan housing 30 is disposed on the lower cover 102 of the electronic apparatus 1, but the disclosure is not limited in this regard. As shown in FIG. 3, the fan base 30a of the fan housing 30 is mounted on the lower cover 102 of the electronic apparatus 1. The fixing shaft 34 of the fan module 3 includes a first end 34a and a second end 34b. The first end 34a of the fixing shaft 34 is mounted to the fan base 30a. In an embodiment, the second end 34b of the fixing shaft 34 protrudes out of the fan cover 30b of the fan housing 30. In the embodiment, the second end 34b that protrudes out of the fan cover 30b are further engaged with the upper cover 100 of the electronic apparatus 1. In practice, the first end 34a of the fixing shaft 34 can also protrude out of the fan base 30a of the fan housing 30 to be engaged with the lower cover 102 of the electronic apparatus 1. As a result, even if an external load deforms the housing (i.e. the upper cover 100 and the lower cover 102) of the electronic apparatus 1, the fan body 38 of the fan module 3 is uneasy to generate noises.

As shown in FIG. 3, the fan base 30a of the fan housing 30 has a hole 30c. The bushing 40 of the fan module 3 is engaged with the hole 30c of the fan base 30a. In the embodiment, the bushing 40 includes a protruding portion 40a and an accommodating trough 40b. The protruding portion 40a of the bushing 40 is engaged with the hole 30c of the fan base 30a. The accommodating trough 40b of the bushing 40 has an indentation 40c. The indentation 40c of the accommodating trough 40b is engaged with the first end 34a of the fixing shaft 34. The protruding portion 40a and the accommodating trough 40b are respectively located at different sides of the bushing 40, and the indentation 40c and the protruding portion 40a are aligned with each other. Hence, the fixing shaft 34 and the fan base 30a of the fan module 3 can be firmly mounted to each other with the assistance of the bushing 40, but the disclosure is not limited in this regard. In an embodiment, the indentation 40c of the accommodating trough 40b can further extend to the protruding portion 40a to form a via, so that the first end 34a of the fixing shaft 34 can pass through the via to be engaged with the lower cover 102 of the electronic apparatus 1, and thus similarly achieve the purpose of firmly mounting the fixing shaft 34 and the fan base 30a.

As shown in FIG. 3, the bearing 36 of the fan module 3 includes a first ring 36a and a second ring 36b. The first ring 36a and the second ring 36b are pivotally connected to each other. The first ring 36a of the bearing 36 is disposed around the outer edge of the fixing shaft 34, so as to be mounted to the fixing shaft 34. The fan body 38 of the fan module 3 is disposed around the outer edge of the second ring 38b of the bearing 38, so that the fan body 38 and the second ring 36b of the bearing 36 can rotate relative to the first ring 36a and the fixing shaft 34 that are stationary and mounted to each other. It can be seen that the first ring 36a of the bearing 36 is within the second ring 36b.

As shown in FIG. 3, the fan body 38 of the fan module 3 includes a fan hub 38a and a plurality of fan blades 38b. The fan hub 38a of the fan body 38 includes a hollow engaging portion 38c. The hollow engaging portion 38c of the fan hub 38a is disposed around the outer edge of the second ring 36b of the bearing 36. The second end 34b of the fixing shaft 34 passes through the hollow engaging portion 38c of the fan hub 38a to be engaged with the upper cover 100 of the electronic apparatus 1. The fan blades 38b of the fan body 38 are radially disposed around the fan hub 38a. In order to improve the convenience of assembling the fan module 3 into the electronic apparatus 1, the upper cover 100 of the electronic apparatus 1 has an engaging trough 100a. The engaging trough 100a of the upper cover 100 is engaged with the second end 34b of the fixing shaft 34. The lower cover 102 of the electronic apparatus 1 can also include a structure (not shown) similar to the engaging trough 100a of the upper cover 100 to be engaged with the first end 34a of the fixing shaft 34.

As shown in FIG. 3, the accommodating trough 40b of the bushing 40 accommodates the fixing shaft 34, the bearing 36, and the hollow engaging portion 38c of the fan body 38. The hollow engaging portion 38c of the fan body 38 and the second ring 36b of the bearing 36 rotate relative to the first ring 36a of the bearing 36 and the fixing shaft 34 in the accommodating trough 40b of the bushing 40. Another purpose of the bushing 40 of the fan module 3 is mounting the stator 42 and the circuit board 44 to the outer edge of the bushing 40. In an embodiment, the stator 42 and the circuit board 44 are disposed around the outer edge of the bushing 40, but the disclosure is not limited in this regard. The stator 42 includes a plurality of coils, and the circuit board 44 is electrically connected to the stator 42. Hence, the currents of the circuit board 44 can flow to the coils of the stator 42, so as to drive the fan body 38 to rotate.

In general, the fan housing 30 is mounted in the electronic apparatus 1 by screws, but the disclosure is not limited in this regard.

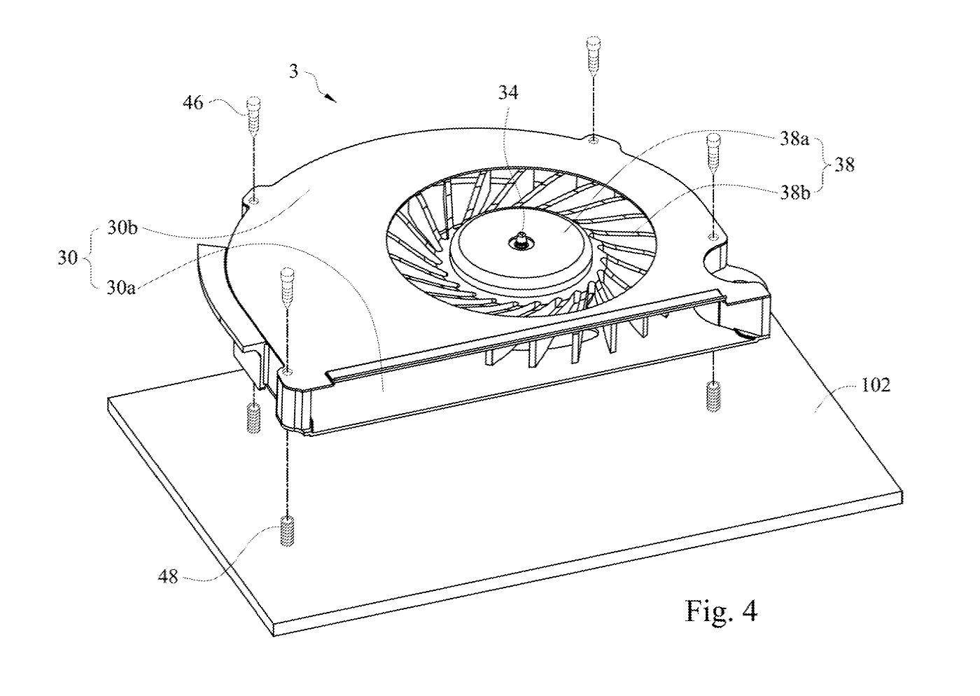

FIG. 4 is an exploded view of the fan module 3 and the lower cover 102 of the electronic apparatus 1 according to an embodiment of the disclosure.

As shown in FIG. 4, the fan housing 30 is mounted in the electronic apparatus 1 by screws 46 and resilient members 48. When the fan housing 30 is mounted on the lower cover 102 of the electronic apparatus 1, the resilient members 48 are disposed between the fan housing 30 and the lower cover 102. The resilient members are springs, elastic plates, or pieces of rubber. When the screws 46 pass through the fixing holes of the fan housing 30 to be mounted to the lower cover 102 of the electronic apparatus 1, the resilient members 48 maintain a space between the fan housing 30 and the lower cover 102 of the electronic apparatus 1. When a large load is applied onto the upper cover 100 of the electronic apparatus 1, the fixing shaft 34 is forced to make the fan housing 30 compress the resilient members 48, so as to prevent the deformed upper cover 100 from affecting the rotation of the rotating components of the fan module 3. Once the large load applied onto the upper cover 100 of the electronic apparatus 1 is disappear, the resilient members 48 recover and make the fan module 3 move bake to the original position, and the heat dissipating capability of the fan module 3 will not be affected.

Therefore, when an external load is applied onto the upper cover 100 of the electronic apparatus 1, the upper cover 100 deforms toward the fan module 3, but the stationary fixing shaft 34 of the fan module 3 supports between the upper cover 100 and the lower cover 102 of the electronic apparatus 1, so as to prevent the deformed upper cover 100 from directly contacting the rotating components (e.g., the fan body 38). So, unexpected noises will not be generated, and the operation of the fan module 3 will not be disturbed. Furthermore, the resilient members 48 that are installed between the fan module 3 and the electronic apparatus 1 can ensure that the rotating components in the fan module 3 will not be affected by the deformed upper cover 100.

It should be pointed out that compared with conventional fan modules, the fan module 3 of the embodiment replaces a rotating shaft that originally rotates with a fan body 38 by the fixing shaft 34, and enhances the bearing capability relative to the upper cover 100 of the electronic apparatus 1 by the fixing shaft 34. Therefore, even if the deformed upper cover 100 of the electronic apparatus 1 compresses the fixing shaft 34 of the fan module 3, the rotation of the fan body 38 will not be affected.

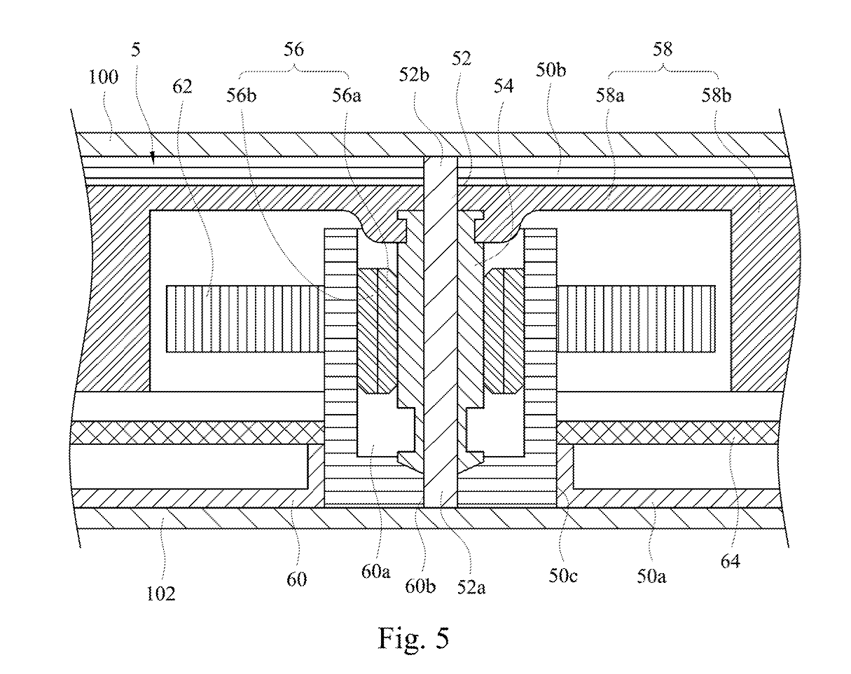

FIG. 5 is a cross-sectional view showing that a fan module 5 is disposed in the electronic apparatus 1 in FIG. 1 according to another embodiment of the disclosure.

As shown in FIG. 5, the fan module 5 includes a fan housing 50, a supporting rib 52, a hollow shaft 54, a bearing 56, a fan body 58, a stator 62, and a circuit board 64. The fan housing 50 of the fan module 5 includes a fan base 50a and a fan cover 50b. The fan base 50a and the fan cover 50b of the fan housing 50 can be mounted to each other by engaging or locking, but the disclosure is not limited in this regard. The fan base 50a of the fan housing 50 is mounted on the lower cover 102 of the electronic apparatus 1. The supporting rib 52 of the fan module 5 includes a first end 52a and a second end 52b. The first end 52a of the supporting rib 52 passes out of the fan housing 50 via the fan base 50a to be connected to the lower cover 102 of the electronic apparatus 1. The second end 52b of the supporting rib 52 passes out of the fan housing 50 via the fan cover 50b to be connected to the upper cover 100 of the electronic apparatus 1. The hollow shaft 54 of the fan module 5 is pivotally connected to the outer edge of the supporting rib 52.

As shown in FIG. 5, the fan base 50a of the fan housing 50 has a hole 50c. The fan module 5 further includes a bushing 60. The bushing 60 of the fan module 5 is engaged with the hole 50c of the fan base 50a. In the embodiment, the bushing 60 has an accommodating trough 60a. The accommodating trough 60a of the bushing 60 has via 60b. The via 60b of the accommodating trough 60a is communicated with the hole 50c of the fan base 50a. Hence, the first end 52a of the supporting rib 52 passes through the via 60b of the accommodating trough 60a and the hole 50c of the fan base 50a to be connected to the lower cover 102 of the electronic apparatus 1.

As shown in FIG. 5, the bearing 56 of the fan module 5 includes a first ring 56a and a second ring 56b. The first ring 56a and the second ring 56b of the bearing 56 are pivotally connected to each other. The first ring 56a of the bearing 56 is disposed around the outer edge of the hollow shaft 54, so as to be mounted to the hollow shaft 54. The second ring 56b of the bearing 56 is mounted on the fan base 50a of the fan housing 50. The fan body 58 of the fan module 5 is disposed around the outer edge of the hollow shaft 54, so that the fan body 58, the hollow shaft 54, and the first ring 56a of the bearing 56 can rotate relative to the stationary supporting rib 52 and the second ring 56b that is mounted to the fan base 50a. It can be seen that the first ring 36a of the bearing 36 is within the second ring 36b.

As shown in FIG. 5, the fan body 58 of the fan module 5 includes a fan hub 58a and a plurality of fan blades 5813. The fan hub 58a of the fan body 58 is disposed around the outer edge of the hollow shaft 54. Furthermore, the position on the outer edge of the hollow shaft 54 at which the fan hub 58a is disposed around is more adjacent to the second end 52b of the supporting rib 52 (i.e., more adjacent to the upper cover 100 of the electronic apparatus 1). The fan blades 58b of the fan body 58 are radially disposed around the fan hub 58a.

As shown in FIG. 5, the accommodating trough 60a of the bushing 60 accommodates the hollow shaft 54 and the bearing 56, and the supporting rib 52 passes through the accommodating trough 60a. In other words, the hollow shaft 54 of the fan module 5 and the first ring 56a of the bearing 56 rotate relative to the second ring 56b of the bearing 56 and the supporting rib 52 in the accommodating trough 60a of the bushing 60. In an embodiment, the stator 62 and the circuit board 64 are disposed around the outer edge of the bushing 60, but the disclosure is not limited in this regard. The stator 62 includes a plurality of coils, and the circuit board 64 is electrically connected to the stator 62. Hence, the currents of the circuit board 64 can flow to the coils of the stator 62, so as to drive the hollow shaft 54 and the fan body 58 to rotate.

Therefore, when an external load is applied onto the upper cover 100 of the electronic apparatus 1, the upper cover 100 deforms toward′ the fan module 5, but the supporting rib 52 of the fan module 5 supports between the upper cover 100 and the lower cover 102 of the electronic apparatus 1, so as to prevent the deformed upper cover 100 from directly contacting the rotating components (e.g., the fan body 58). So, unexpected noises will not be generated, and the operation of the fan module 5 will not be disturbed.

It should be pointed out that compared with the conventional fan modules, the fan module 5 of the embodiment install the supporting rib 52 at the original location of the rotating axis, and enhances the bearing capability relative to the upper cover 100 of the electronic apparatus 1 by the supporting rib 52. Therefore, the concept of the disclosure can be simply and widely applied to all of the conventional fan modules.

According to the foregoing recitations of the embodiments of the disclosure, it can be seen that the fan module replaces a rotating shaft that originally rotates with a fan body by a fixing shaft, and protrudes the fixing shaft out of the fan module to bear loads, so as to prevent the problem that the fan body stops rotating caused by an external load. In addition, the fan module of the present disclosure can also additionally install a supporting rib at the original location of the rotating axis and passes the supporting rib out of the fan module to bear loads, so as to prevent the problem that the fan body stops rotating caused by an external load.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fail within the scope of the following claims.

What is claimed is:

1. A fan module used in an electronic apparatus, the electronic apparatus comprising an upper cover and a lower cover, the fan module comprising:
a fan housing mounted between the upper cover and the lower cover;
a fixing shaft comprising a first end and a second end, the first end being mounted on the fan housing, the second end passing out of the fan housing;
a bearing comprising a first ring and a second ring, the first ring being pivotally connected to the second ring and disposed around the outer edge of the fixing shaft; and
a fan body disposed around the outer edge of the second ring, so as to rotate relative to the fixing shaft.

2. The fan module of claim 1, wherein the fan body further comprises:
a fan hub comprising a hollow engaging portion disposed around the outer edge of the second ring, wherein the second end passes through the hollow engaging portion to be engaged with the upper cover; and
a plurality of fan blades disposed around the fan hub.

3. The fan module of claim 2, wherein the fan housing has a hole, the fan module further comprises a bushing, and the bushing is engaged with the hole.

4. The fan module of claim 3, wherein the bushing further comprises:
a protruding portion engaged with the hole; and
an accommodating trough accommodating the hollow engaging portion and the bearing, the accommodating trough having an indentation engaged with the first end.

5. The fan module of claim 3, wherein the bushing further comprises:
a protruding portion engaged with the hole; and
an accommodating trough accommodating the fixing shaft, the bearing, and the hollow engaging portion, the accommodating trough having a via, wherein the first end passes through the via to be engaged with the lower cover.

6. The fan module of claim 3, further comprising a stator mounted at the outer edge of the bushing and working together with the fan body.

7. The fan module of claim 6, further comprising a circuit board mounted at the outer edge of the bushing and electrically connected to the stator.

8. The fan module of claim 1, wherein the fan housing is mounted on the lower cover.

9. The fan module of claim 8, wherein the second end passes out of the fan housing and is engaged with the upper cover.

10. The fan module of claim 8, wherein the first end passes out of the fan housing and is engaged with the lower cover.

11. The fan module of claim 8, further comprising a resilient member disposed between the fan housing and the lower cover.

12. A fan module used in an electronic apparatus, the electronic apparatus comprising an upper cover and a lower cover, the fan module comprising:
a fan housing mounted on the lower cover;
a supporting rib comprising a first end and a second end, the first end passing out of the fan housing to be connected to the lower cover, the second end passing out of the fan housing to be connected to the upper cover;
a hollow shaft pivotally connected to the outer edge of the supporting rib;
a bearing comprising a first ring and a second ring, the first ring being pivotally connected to the second ring and disposed around the outer edge of the hollow shaft, the second ring being mounted on the fan housing; and
a fan body disposed around the outer edge of the hollow shaft, so as to rotate relative to the supporting rib together with the hollow shaft.

13. The fan module of claim 12, wherein the fan body further comprise
a fan hub disposed around the outer edge of the hollow shaft; and
a plurality of fan blades disposed around the fan hub.

14. The fan module of claim 13, wherein the fan housing has a hole, the fan module further comprises a bushing, and the bushing is engaged with the hole.

15. The fan module of claim 14, wherein the bushing further comprises an accommodating trough accommodating the hollow shaft and the bearing, the accommodating trough has a via communicated with the hole, and the first end passes through the via and the hole to be connected to the lower cover.

16. The fan module of claim 14, further comprising a stator mounted at the outer edge of the bushing and working together with the fan body.

17. The fan module of claim 16, further comprising a circuit board mounted at the outer edge of the bushing and electrically connected to the stator.

18. The fan module of claim 12, further comprising a resilient member disposed between the fan housing and the lower cover.

19. The fan module of claim 18, wherein the resilient member is a spring, an elastic plate, or a rubber.
